(19) United States
(12) Patent Application Publication
(10) Pub. No.: US 2025/0323608 A1
(43) Pub. Date: Oct. 16, 2025

(54) LOGARITHMIC SIGNAL AMPLIFICATION

(71) Applicant: Infineon Technologies AG, Neubiberg (DE)

(72) Inventors: Jose Luis Ceballos, Villach (AT); Fulvio Ciciotti, Bad Bleiberg (AT); Andreas Wiesbauer, Pörtschach (AT); Dietmar Straeussnigg, Villach (AT); Christopher Igor Rogi, Villach (AT); Christian Schranz, Feldkirchen (AT)

(21) Appl. No.: 18/637,078

(22) Filed: Apr. 16, 2024

(51) Int. Cl. H03F 3/21; H03F 1/32

(52) U.S. Cl. CPC H03F 3/211; H03F 1/3211; H03F 2200/03

(57) ABSTRACT

A logarithmic amplifier system is disclosed. The system includes first and second amplifiers respectively having first and second gains; a first multiplier having an input connected to an output of the first amplifier, and being configured to output a first multiplied signal based on an output signal of the first amplifier and based on a received first multiplication factor equal to a value K; a second multiplier having an input connected to an output of the second amplifier, and being configured to output a second multiplied signal based on an output signal of the second amplifier and based on a received second multiplication factor equal to 1 minus the value K; a transition shaping circuit configured to change the value K from 0 to 1 with a filtered transfer function; and a summing circuit having inputs coupled to outputs of the first multiplier and the second multiplier.

### TECHNICAL FIELD

The present invention relates generally to logarithmic systems, and, in particular embodiments, to low noise and distortion microphones.

### BACKGROUND

Digital microphones generally include a microelectromechanical system (MEMS) device that is responsive to ambient sound waves, a programmable gain amplifier (PGA) for amplifying an analog signal generated by the MEMS device, an analog-to-digital converter (ADC) for converting the analog signal into a digital signal, and digital signal processing circuitry to provide a digital output signal that corresponds to the input analog signal in an format requested by a customer. While single-ended and differential PGA amplifiers for digital microphones are known, market trends compel the increasing use of low noise PGA amplifiers with improved signal-to-noise ratios (SNR) and distortion performance, as well as the ability to handle wide signal swings from the MEMS device without degrading performance.

### SUMMARY

One embodiment is a logarithmic amplifier system, including first and second amplifiers, the first amplifier having a first gain, and the second amplifier having a second gain; a first multiplier having an input connected to an output of the first amplifier, and being configured to output a first multiplied signal based on an output signal of the first amplifier and based on a received first multiplication factor equal to a value K; a second multiplier having an input connected to an output of the second amplifier, and being configured to output a second multiplied signal based on an output signal of the second amplifier and based on a received second multiplication factor equal to 1 minus the value K; a transition shaping circuit configured to generate the value K, where the transition shaping circuit is configured to change the value K from 0 to 1 with a filtered transfer function; and a summing circuit having inputs coupled to outputs of the first multiplier and the second multiplier.

Another embodiment is a method of using a logarithmic amplifier system, the method including generating a first amplified signal based on an analog input and based on a first gain; generating a second amplified signal based on the analog input and based on a second gain; generating a first multiplied signal based on the first amplified signal and based on a first multiplication factor equal to a value K; generating a second multiplied signal based on the second amplified signal and based on a second multiplication factor equal to 1 minus the value K; changing the value K from 0 to 1 with a filtered transfer function; and generating an analog output signal by summing the first and second multiplied signals.

Another embodiment is a digital microphone, including a MEMS device configured to generate an analog signal; and a logarithmic amplifier system, including first and second amplifiers, the first amplifier having a first gain, and the second amplifier having a second gain; a first multiplier having an input connected to an output of the first amplifier, and being configured to output a first multiplied signal based on an output signal of the first amplifier and based on a received first multiplication factor equal to a value K; a second multiplier having an input connected to an output of the second amplifier, and being configured to output a second multiplied signal based on an output signal of the second amplifier and based on a received second multiplication factor equal to 1 minus the value K; a transition shaping circuit configured to generate the value K, where the transition shaping circuit is configured to change the value K from 0 to 1 with a filtered transfer function; and a summing circuit having inputs coupled to outputs of the first multiplier and the second multiplier.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a block diagram of an exemplary logarithmic amplifier system comprising an analog programmable gain amplifier, an analog-to-digital converter (ADC), and a digital anti-logarithmic component according to some embodiments;

FIG. 2 is a is a logarithmic amplifier system comprising a continuous or filtered analog logarithmic programmable gain amplifier (PGA) and summing circuit, an analog-to-digital converter (ADC), and a digital anti-logarithmic component, according to some embodiments;

FIG. 3 is a set of waveform diagrams illustrating smooth gain transition control according to some embodiments;

FIG. 4 is a signal flow diagram illustrating a system for generating a gain control signal according to some embodiments;

FIG. 5 is a is a logarithmic amplifier system comprising a continuous or filtered analog logarithmic programmable gain amplifier (PGA) and summing circuit, an analog-to-digital converter (ADC), and a digital anti-logarithmic component, according to some embodiments;

FIG. 6 is a is a logarithmic amplifier system comprising a quantized analog logarithmic programmable gain amplifier (PGA) and summing circuit, an analog-to-digital converter (ADC), according to some embodiments;

FIG. 7 is a flowchart of a method according to some embodiments; and

FIG. 8 is a block diagram of a digital microphone product, according to some embodiments.

### DETAILED DESCRIPTION OF ILLUSTRATIVE EMBODIMENTS

Illustrative embodiments of the system and method of the present disclosure are described below. In the interest of clarity, all features of an actual implementation may not be described in this specification. It will of course be appreciated that in the development of any such actual embodiment, numerous implementation-specific decisions may be made to achieve the developer's specific goals, such as compliance with system-related and business-related constraints, which will vary from one implementation to another. Moreover, it should be appreciated that such a development effort might be complex and time-consuming but would nevertheless be a routine undertaking for those of ordinary skill in the art having the benefit of this disclosure.

In some embodiments, proper processing of high magnitude signals and/or having high SNR and low distortion is beneficial for the new families of Silicon Microphones.

In some embodiments, Automatic Gain Control (AGC) procedures are used in audio systems. In some embodiments, compressing and decompressing in a smooth way is of interest, and minimizing delays in the signal chain is also beneficial.

In general, low-pass filters may be used to reduce noise folding, for example, in delta-sigma approaches. But low-pass filters may introduce delay and linear distortion. In some embodiments, low-pass filters are not used.

In some embodiments, automatic gain control (AGC) fading-in/fading-out is implemented with a mixed-signal solution. This allows for use of reduced circuitry, area, and power.

In some embodiments, the AGC is implanted using multiple amplifier/sampler signal path gains. The gains can be switched smoothly by means of one or more control signal which fade-in and out the multiple amplifier/sampler signal path simultaneously. The control signal avoids fast jumps (discontinuities) and therefore avoids the need for a filter for decompression.

In some embodiments, offset in the analog domain is compensated in the digital domain. For a constant offset (over PVT) this can be implemented with low effort. For varying offset (for instance temperature dependent) efficient adaptive algorithms can be used (e.g. gradient based algorithms).

In some embodiments, gain mismatch is minimized by calibration methods.

In some embodiments, fast transitions between gain levels are avoided. For example, in some embodiments, a control signal is low-pass filtered to get the smoother transitions.

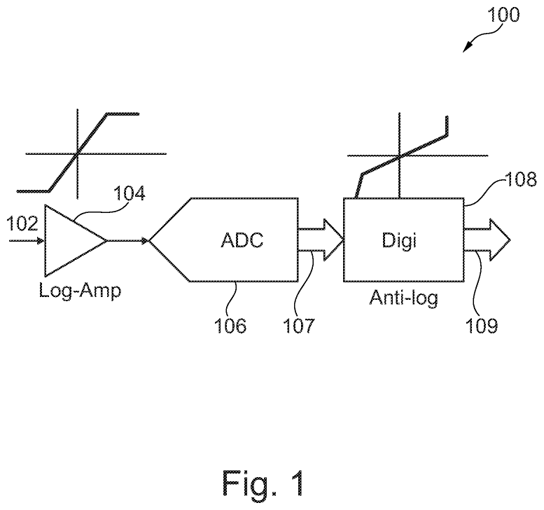

FIG. 1 is a block diagram of an exemplary logarithmic amplifier system 100 comprising a logarithmic programmable gain amplifier, an analog-to-digital converter (ADC), and a digital anti-logarithmic component according to some embodiments. Logarithmic amplifier system 100 includes a logarithmic programmable gain amplifier 104 for receiving an analog input signal 102 (which may be generated by a MEMS device, not shown in FIG. 1), an analog-to-digital converter (ADC) 106, and a digital anti-logarithmic component 108. In some embodiments, logarithmic programmable gain amplifier 104 is substantially logarithmic. In some embodiments, logarithmic programmable gain amplifier 104 is substantially piecewise logarithmic. ADC 106 is coupled to the digital anti-logarithmic component 108 through digital bus 107. The digital anti-logarithmic component 108 comprises an output bus 109 that provides a linearized digital signal. The analog programmable gain amplifier 104 has a logarithmic transfer function, for example, due to the saturation of the amplifier(s), and the digital anti-logarithmic component 108 has an anti-logarithmic transfer function.

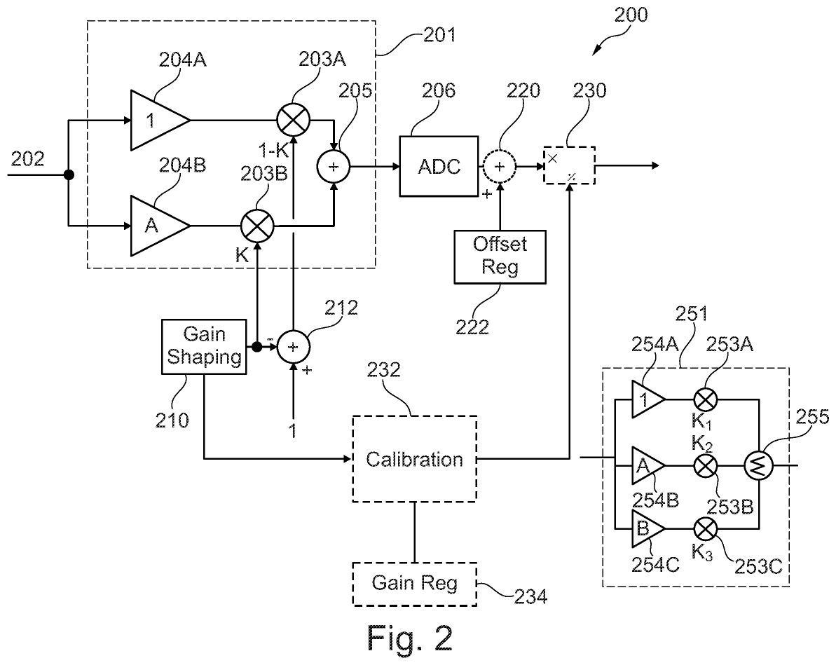

FIG. 2 illustrates various aspects for an embodiment using two amplifiers, but can be extended to any number of amplifiers. The two amplifiers/samplers present two different signal path gains. These gains can be switched smoothly by means of a control signal which fades-in and out both channels simultaneously. The control signal avoids fast jumps (discontinuities). As a result, the filter typically seen in related or similar circuits is avoided.

FIG. 2 is a logarithmic amplifier system 200 comprising a continuous or filtered analog logarithmic programmable gain amplifier (PGA) having an amplifier stage 201 with individual amplifiers 204A and 204B each receiving an analog input signal at node 202 (which may be generated by a MEMS device, not shown in FIG. 2), multipliers 203A and 203B, and summing circuit 205.

In alternative embodiments, logarithmic amplifier system 200 comprises a continuous or filtered analog logarithmic PGA having an amplifier stage 251 with individual amplifiers 254A, 254B, and 254C, each receiving an analog input signal at node 202, multipliers 253A, 253B, and 253C, and summing circuit 255. In some embodiments, logarithmic amplifier system 200 includes 3, 4, or more individual amplifiers and multipliers, and a corresponding summing circuit.

Logarithmic amplifier system 200 also includes analog-to-digital converter (ADC) 206, gain transition shaping circuit 210, and transition summing circuit 212. In some embodiments, logarithmic amplifier system 200 includes optional offset summing circuit 220 and optional offset register 222. In some embodiments, logarithmic amplifier system 200 includes optional gain adjust circuit 230, optional gain calibration circuit 232, and optional gain register 234.

Each individual amplifier 204A and 204B or 254A, 254B, and 254C has a linear or substantially linear gain until it saturates for a given (increasing) maximum amplitude input signal. While two individual amplifiers are shown in FIG. 2, any number greater than or equal to two can be used. Many suitable amplifier architectures are known in the art. Any suitable architecture may be used.

In the illustrated embodiment, amplifier 204A or 254B has unity gain. In alternative embodiments, amplifier 204A or 254A has a different gain value. Amplifier 204A or 254A is configured to generate a signal for multiplier 203A or 253A which is a multiplied version of analog input signal at node 202, where the gain of amplifier 204A or 254B determines the multiplication factor.

In the illustrated embodiment, amplifier 204B or 254B has a gain of A. In alternative embodiments, amplifier 204A or 254A has a different gain value. In some embodiments, A is designed to be a particular factor greater than the gain of amplifier 204A or 254A. Amplifier 204B or 254B is configured to generate a signal for multiplier 203B or 253B which is a multiplied version of analog input signal at node 202, where the gain of amplifier 204B or 254B determines the multiplication factor.

In embodiments using amplifier stage 251, amplifier 254C has a gain of B. In alternative embodiments, amplifier 254C has a different gain value. In some embodiments, B is designed to be a particular factor greater than the gain of amplifier 254B. In some embodiments, B/A is equal to A/1, or B is equal to A squared. Amplifier 254C is configured to generate a signal for multiplier 253C which is a multiplied version of analog input signal at node 202, where the gain of amplifier 254C determines the multiplication factor.

Each of the multipliers 203A and 203B or 253A, 253B, and 253C receives a transition control signal from gain transition shaping circuit 210, where multiplier 203B receives a transition control signal having a value of 1-K from transition summing circuit 212, and where multiplier 203A receives a transition control signal having a value of K, or where multiplier 253A receives a transition control signal having a value of K1 from transition summing circuit 212, where multiplier 253B receives a transition control signal having a value of K2, and where multiplier 253C receives a transition control signal having a value of K3.

Multipliers 203A and 203B or 253A, 253B, and 253C multiply the respective amplifier output by the received transition control signal value. In addition, each of multipliers 203A and 203B or 253A, 253B, and 253C generate a signal for a corresponding input of a summing circuit 205 or 255, where the signal multiplier 203A generates is equal or substantially equal to the analog input signal times the gain of amplifier 204A times the value 1-K, and where the signal multiplier 203B generates is equal or substantially equal to the analog input signal times the gain of amplifier 204B times the value K, or where the signal multiplier 253A generates is equal or substantially equal to the analog input signal times the gain of amplifier 254A times the value K1, the signal multiplier 253B generates is equal or substantially equal to the analog input signal times the gain of amplifier 254A times the value K2, and the signal multiplier 253C generates is equal or substantially equal to the analog input signal times the gain of amplifier 254A times the value K3.

In some embodiments, the value K, determined by gain transition shaping circuit 210, is less than one, and accordingly represents a proportioned weight of the contribution of the signal generated by amplifier 204B to the output of summing circuit 205 with respect to the contribution of the signal generated by amplifier 204A to the output of summing circuit 205. Accordingly, if the value K is 1, the output of summing circuit 205 is equal to or is substantially equal to the signal generated by amplifier 204B, and if the value K is equal to 0, the output of summing circuit 205 is equal to or is substantially equal to the signal generated by amplifier 204A. As discussed in further detail below, gain transition shaping circuit 210 is configured to generate and change the value of K such that transitions of the output of summing circuit 205 between being equal to the signal generated by amplifier 204A and being equal to the signal generated by amplifier 204B are smooth and continuous or filtered or substantially continuous or filtered. For example, in some embodiments, transitions of the output of summing circuit 205 are continuous or filtered or substantially continuous or filtered because discontinuities in the output of summing circuit 205 are generated because of the multibit resolution of the digital K value, instead of, for example, abrupt changes in which of amplifiers 204A and 204B are used to generate a signal for ADC 206.

In embodiments using amplifier stage 251, gain transition shaping circuit 210 determines the values of K1, K2, and K3. For example, gain transition shaping circuit 210 may determine the values of K1, K2, and K3 so that at any particular time one of the values K1, K2, and K3 is equal to one and the others of values K1, K2, and K3 are equal to zero. In addition, gain transition shaping circuit 210 may be configured to change the values of K1, K2, and K3 so that another of the values K1, K2, and K3 transitions to be equal to one and the others of values K1, K2, and K3 transition to or remain at zero. Accordingly, gain transition shaping circuit 210 may be configured to transition one of the values K1, K2, and K3 from one to zero while transitioning another of the values K1, K2, and K3 from zero to one. In some embodiments, gain transition shaping circuit 210 may be configured to transition the one of the value K1, K2, or K3 from one to zero and to transition the other of the values K1, K2, or K3 from zero to one so that K1=1−K2 or so that K2=1−K3 during the transition.

Accordingly, the individual amplifiers gains combine to generate a weighted composite transfer function, and summing circuit 205 or 254 provides a substantially continuous or filtered or substantially continuous or filtered logarithmic transfer function across the entire range of the analog input.

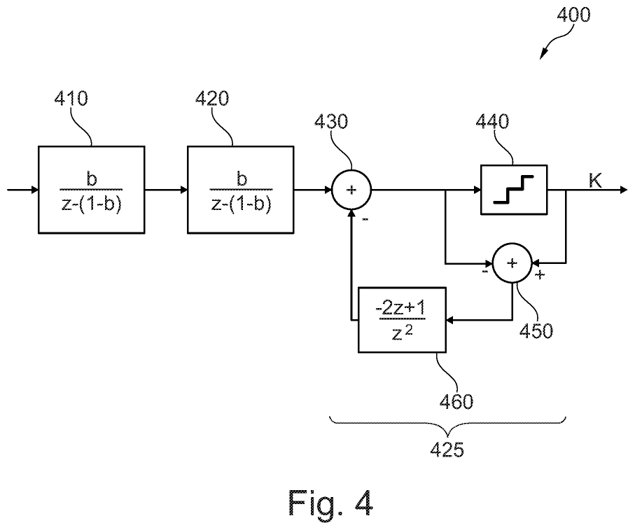

Gain transition shaping circuit 210 may generate the value K or K1, K2 and K3 using digital logic. For example, in some embodiments, gain transition shaping circuit 210 includes digital logic which generates the value K or K1, K2, and K3 using principles similar or identical to those illustrated in the signal flow graph of FIG. 4, discussed below.

In some embodiments, gain transition shaping circuit 210 includes a comparator (not shown) or includes an ADC (not shown), such as a flash ADC. The comparator or ADC digitizes the analog input signal and generates a trigger signal for the digital logic. In response to the trigger signal, the digital logic changes the value K or K1, K2, and K3 based on the digitized analog input signal. In some embodiments, gain transition shaping circuit 210 includes a comparator circuit (not shown) which compares an output of ADC 206 to one or more threshold values. Accordingly, the changes in the value K or K1, K2, and K3 are generated in response to the analog input signal transitioning across one or more threshold boundaries. For example, gain transition shaping circuit 210 may determine that the gain of amplifier stage 201 or 251 should be changed based on one or more characteristics of the analog input signal, for example, including magnitude, average magnitude over a predetermined time, frequency, etc. In some embodiments, the digital logic has programmable thresholds. In some embodiments, the digital logic is hysteretic. In some embodiments, gain transition shaping circuit 210 includes a threshold detector which is used to compare the digitized analog input to one or more thresholds to detect conditions for changing the gain of the logarithmic amplifier system 200.

In some embodiments, gain transition shaping circuit 210 includes a threshold detector which is used to compare the analog input to one or more thresholds to detect conditions for changing the gain of the logarithmic amplifier system 200.

Analog-to-digital converter (ADC) 206 has an input coupled to the output of the summing circuit 205 and is configured to generate a digital representation of the logarithmically compressed analog signal received from summing circuit 205.

In some embodiments, gain adjust circuit 230 generates an output that provides a linearized digital signal because of an anti-logarithmic transfer function applied to the digital logarithmic signal received on from ADC 206, where the anti-logarithmic transfer function is a result of input from gain calibration circuit 232. Accordingly, in some embodiments, signal compression is performed in the analog domain using the continuous or filtered approach described above, and the signal decompression is performed in the digital domain.

In some embodiments, logarithmic amplifier system 200 includes an optional offset calibration capability provided, in part, by summing circuit 220 and offset register 222. In some embodiments, logarithmic amplifier system 200 includes an undesirable parasitic offset, which may be calibrated for. For example, a calibration routine may be performed to determine one or more offset values for offset register 222. In addition, during normal operation, summing circuit 220 adds an offset value to the digital representation of the logarithmically compressed analog signal generated by ADC 206.

In some embodiments, during the calibration routine, a 0 volts or minimum scale analog signal is input to the logarithmic amplifier system 200 as the analog input signal, and a first output of the ADC 206 is measured with the value K set to 1, and a second output of the ADC 206 is measured with the value K set to 0. In addition, the offset register 222 may be programmed with one or more offset values based on measurements taken during the calibration routine. For example, offset register 222 may be programmed with a linear series of offset values. In some embodiments, the linear series starts from a first offset value which compensates for the offset of amplifier 204A, as determined based on the second output and linearly steps to a second offset value which compensates for the offset of amplifier 204B, as determined based on the first output.

In normal operation, a particular offset value of the linear series is selected based on a current value of K.

In some embodiments, other offset calibration routines and offset calibration techniques are used. For example, in some embodiments, a single offset value is programmed into offset register 222, based, for example, on an average of a first offset value which compensates for the offset of amplifier 204A, as determined based on the second output and a second offset value which compensates for the offset of amplifier 204B, as determined based on the first output.

In some embodiments, efficient adaptive algorithms are used. For example, a gradient based algorithm may be used to determine offset values based on continuous or repeated monitoring.

In some embodiments, logarithmic amplifier system 200 includes an optional gain calibration capability provided, in part, by gain adjust circuit 230, optional gain calibration circuit 232, and optional gain register 234. In some embodiments, a gain of logarithmic amplifier system 200 may be adjusted to a particular target gain.

For example, a gain calibration routine may be performed to determine one or more gain calibration values for gain register 234. In addition, during normal operation, optional gain adjust circuit 230 multiplies or divides the digital representation of the logarithmically compressed analog signal from ADC 206 (and optionally adjusted by optional offset summing circuit 220) by a value determined by optional gain calibration circuit 232 based on the gain calibration values stored in gain register 234. The multiplication or division by gain adjust circuit 230 results in an anti-logarithmic transfer function being applied to the signal from ADC 206.

In some embodiments, during the gain calibration routine, a static full scale analog signal is input to the logarithmic amplifier system 200 as the analog input signal, and a first output of the ADC 206 is measured with the value K set to 1, and a second output of the ADC 206 is measured with the value K set to 0. In addition, the gain register 234 may be programmed with one or more offset values based on measurements taken during the calibration routine. For example, gain register 234 may be programmed with a linear series of gain calibration values. In some embodiments, the linear series starts from a first gain calibration value which compensates for the gain offset of amplifier 204A, as determined based on the second output and linearly steps to a second gain calibration value which compensates for the gain mismatch of amplifier 204B, as determined based on the first output.

In normal operation, a particular gain calibration value of the linear series is selected based on a current value of K.

In some embodiments, other gain calibration routines and gain calibration techniques are used. For example, in some embodiments, a single gain calibration value is programmed into gain register 234, based, for example, on an average of a first gain calibration value which compensates for the gain calibration of amplifier 204A, as determined based on the second output and a second gain calibration value which compensates for the gain calibration of amplifier 204B, as determined based on the first output.

In embodiments using more than two amplifiers, similar principles may be used. For example, in some embodiments, the logarithmic amplifier system includes a series of amplifiers, each of greater gain than the previous. In addition, each pair of amplifiers which are adjacent in order of amplification has a pair of multipliers analogous to multipliers 203A and 203B in their relationship with amplifiers 204A and 204B, and in their relationship to one another as far as their K and 1-K multiplication factors.

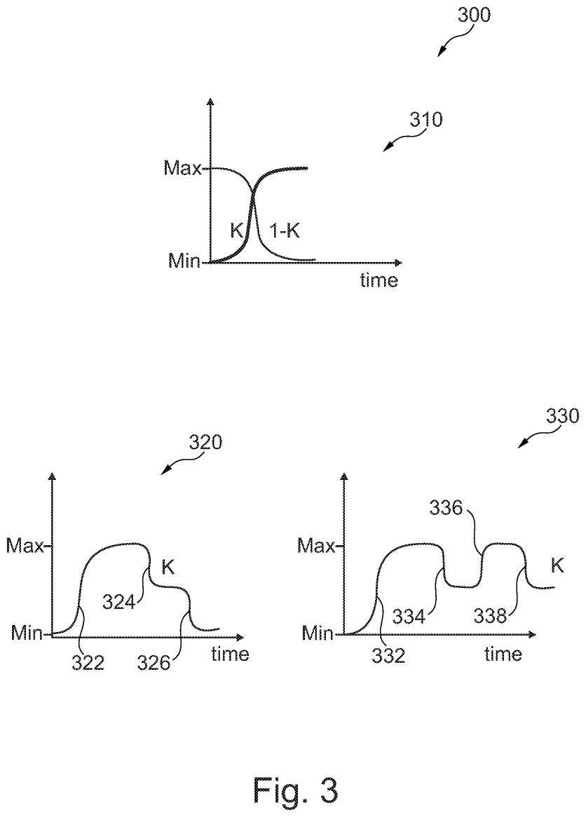

FIG. 3 is a set of waveform diagrams illustrating smooth gain transition control according to some embodiments. The waveform diagrams illustrate examples of the value K and the value 1-K, for example, as generated by gain transition shaping circuit 210, for example, in response to a gain change trigger signal according to some embodiments. In alternative embodiments, gain transition shaping circuit 210 is configured to generate different values of K and 1-K, for example, as a result of having differing filtering characteristics.

Waveform 310 illustrates a relationship between the value K and the value 1-K. As illustrated, as the value K transitions from a minimum, for example 0, to a maximum, for example 1, the value 1-K transitions from the maximum to the minimum.

Waveform 320 illustrates an example of first, second, and third transitions 322, 324, and 326 of the value K. During the first transition 322, the value K transitions from the minimum to the maximum. During the second transition 324, the value K transitions from the maximum to a midpoint value between the minimum and maximum. During the third transition 326, the value K transitions from the midpoint value to the minimum. The midpoint value may be any value between the minimum and the maximum.

In some embodiments, it may be advantageous to relatively quickly, but smoothly, transition from the minimum to the maximum, for example as illustrated in the first transition 322. For example, in some embodiments, the first transition 322 has a time or frequency characteristic corresponding with a high audio range frequency, such as about 20 kHz. In some embodiments, it may be advantageous to relatively slowly and smoothly transition from the maximum to the minimum, for example as illustrated by the combination of the second and third transitions 324 and 326.

In alternative embodiments, gain transition shaping circuit 210 is advantageously configured to relatively quickly, but smoothly, transition from the maximum to the minimum. In some embodiments, gain transition shaping circuit 210 is advantageously configured to relatively slowly and smoothly transition from the minimum to the maximum, for example, by transitioning from the minimum to the midpoint value, and subsequently transitioning from the midpoint value to the maximum.

Waveform 330 illustrates an example of first, second, third, and fourth transitions 332, 334, 336, and 338 of the value K. During the first transition 332, the value K transitions from the minimum to the maximum. During the second transition 334, the value K transitions from the maximum to a midpoint value between the minimum and maximum. During the third transition 336, the value K transitions from the midpoint value to the maximum. During the fourth transition 338, the value K transitions from the maximum to the midpoint value.

In some embodiments, it may be advantageous for the value K to, after transitioning from the maximum to the midpoint, transition from the midpoint back to the maximum, as illustrated by transition 336. The value K may then subsequently again transition from the maximum to the midpoint, and thereafter transition either to the minimum or again to the maximum.

In alternative embodiments, gain transition shaping circuit 210 is advantageously configured to cause the value K to, after transitioning from the minimum to the midpoint, transition from the midpoint back to the minimum.

FIG. 4 is a signal flow diagram 400 illustrating a digital processor system for generating a gain transition control signal according to some embodiments. For example, in some embodiments, gain transition shaping circuit 210 operates according to the signal flow diagram to generate a transition control signal.

In some embodiments, the value K is generated using a multibit noise shaper to get only few bits with high resolution during the transitions.

Signal flow diagram 400 includes first one pole low-pass filter 410, second one pole low-pass filter 420, first summing junction 430, quantizer 440, second summing junction 450, and filter 460.

First and second one pole low-pass filters 410 and 420 receive the input signal, and collectively perform a two pole low-pass filter operation on the received input signal. The filtered signal is passed to second order delta-sigma error feedback structure 425, which includes first summing junction 430, quantizer 440, second summing junction 450, and filter 460.

In alternative embodiments, first and second one pole low-pass filters 410 and 420 may be replaced with a raised-cosine filter or similar, for example, to reduce or eliminate group delay distortion.

First summing junction 430 receives the filtered signal and subtracts an error signal therefrom. The error signal is generated by filter 460. The output generated by first summing junction 430 is provided to quantizer 440 and two second summing junction 450.

Quantizer 440 generates a quantized output having the value K, which is also provided to second summing junction 450. In addition, second summing junction 450 subtracts the output generated by first summing junction 430 from the quantized output, and provides the result to filter 460. In some embodiments, the feedback and quantization is implemented with a truncation operation which feeds back a number of LSBs.

Furthermore, filter 460 generates the error signal for first summing junction 430.

In some embodiments of the circuit implementation of the second order delta-sigma error feedback structure 425, the bits of the value K are “anded” with a sampler clocks to control sample switches in the delta sigma input switched capacitor branches. In some embodiments, sampling capacitors are split in several slices that are controlled independently by the gated sampler clock to implement the multiplying functions of the second order delta-sigma error feedback structure 425.

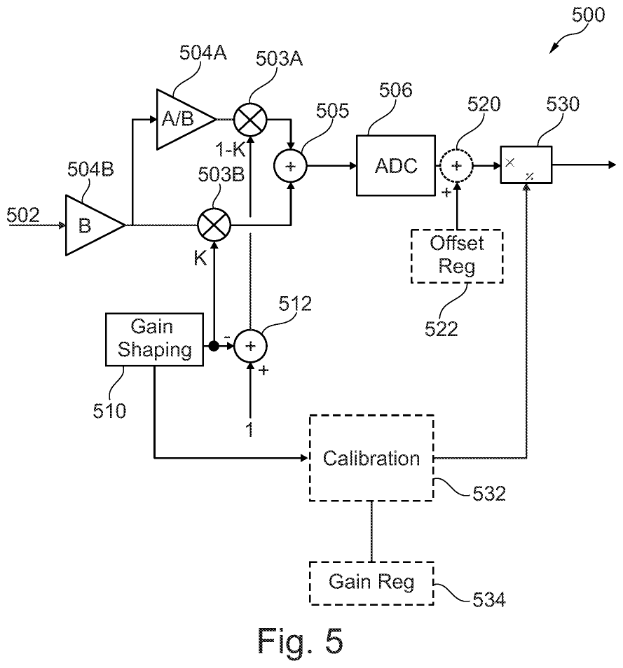

FIG. 5 illustrates various aspects for an embodiment using two amplifiers, but can be extended to any number of amplifiers. The two amplifiers/samplers present two different signal path gains. These gains can be switched smoothly by means of a control signal which fades-in and out both channels simultaneously. The control signal avoids fast jumps (discontinuities). As a result, the filter typically seen in related or similar circuits is avoided.

FIG. 5 is a logarithmic amplifier system 500 comprising a continuous or filtered analog logarithmic programmable gain amplifier (PGA) having individual amplifiers 504A and 504B each receiving an analog input signal at node 502 (which may be generated by a MEMS device, not shown in FIG. 5). In some embodiments, logarithmic amplifier system 200 includes 2, 3, 4, or more individual amplifiers. Amplifier 504A has a gain of A/B and amplifier 504B has a gain of B. In some embodiments, A is greater than B.

Logarithmic amplifier system 500 also includes multipliers 503A and 503B, summing circuit 505, analog-to-digital converter (ADC) 506, gain transition shaping circuit 510, and transition summing circuit 512. In some embodiments, logarithmic amplifier system 500 includes optional offset summing circuit 520 and optional offset register 522. In some embodiments, logarithmic amplifier system 500 includes optional gain adjust circuit 530, optional gain calibration circuit 532, and optional gain register 534.

Each individual amplifier 504A and 504B has a linear or substantially linear gain until it saturates for a given (increasing) maximum amplitude input signal. While two individual amplifiers are shown in FIG. 5, any number greater than or equal to two can be used. Many suitable amplifier architectures are known in the art. Any suitable architecture may be used.

In the illustrated embodiment, amplifier 504A has gain of A/B. In alternative embodiments, amplifier 504A has a different gain value. Amplifier 504A is configured to generate a signal for multiplier 503A which is a multiplied version of analog input signal at node 502, where the gain of amplifier 504A times the gain of amplifier 504B determines the multiplication factor.

In the illustrated embodiment, amplifier 504B has a gain of B. In alternative embodiments, amplifier 504A has a different gain value. Amplifier 504B is configured to generate a signal for amplifier 504A and for multiplier 503B which is a multiplied version of analog input signal at node 502, where the gain of amplifier 504B determines the multiplication factor.

Accordingly, multiplier 503B receives a signal which is the analog input signal times the gain B. In addition, multiplier 503A receives a signal which is the analog input signal times the gain B times the gain A/B. Accordingly, multiplier 503A receives a signal which is the analog input signal times A.

An advantage of logarithmic amplifier system 500 is that when the amplifier 504A saturates, there is no capacitive kickback to the device generating the analog input signal through node 502. In contrast, circuits where multiple amplifiers receive the analog input signal, each amplifier presents a voltage dependent input capacitance. While the voltage dependent input capacitance may be bootstrapped for small signal amplitudes, it may be equal to the full input MOSFET gate to source capacitance at full scale (saturation) signal levels. For example, if the amplifier has a source follower (SF) structure, the gate to source capacitance of the input transistor is bootstrapped. Furthermore, when the amplifier saturates, because the source voltage is fixed to the rail voltage, the input (gate) cannot be “followed” by the source and the input node presents the gate to source capacitance of the input transistor as a load.

Each of the multipliers 503A and 503B receives a transition control signal from gain transition shaping circuit 510, where multiplier 503B receives a transition control signal having a value of 1-K from transition summing circuit 512, and where multiplier 503A receives a transition control signal having a value of K. In some embodiments, multiplier 503A receives the transition control signal having a value of 1-K from transition summing circuit 512, and multiplier 503B receives the transition control signal having a value of K. Multipliers 503A and 503B multiply the respective amplifier output by the received transition control signal value. In addition, each of multipliers 503A and 503B generate a signal for a corresponding input of a summing circuit 505, where the signal multiplier 503A generates is equal or substantially equal to the analog input signal times the gain of amplifier 504B times the gain of amplifier 504A times the value 1-K, and where the signal multiplier 503B generates is equal or substantially equal to the analog input signal times the gain of amplifier 504B times the value K.

In some embodiments, the value K, determined by gain transition shaping circuit 510, is less than one, and accordingly represents a proportioned weight of the contribution of the signal generated by amplifier 504B to the output of summing circuit 505 with respect to the contribution of the signal generated by amplifier 504A to the output of summing circuit 505. Accordingly, if the value K is 1, the output of summing circuit 505 is equal to or is substantially equal to the signal generated by amplifier 504B, and if the value K is equal to 0, the output of summing circuit 505 is equal to or is substantially equal to the signal generated by amplifier 504A. As discussed in further detail below, gain transition shaping circuit 510 is configured to generate and change the value of K such that transitions of the output of summing circuit 505 between being equal to the signal generated by amplifier 504A and being equal to the signal generated by amplifier 504B are smooth and continuous or filtered or substantially continuous or filtered. For example, in some embodiments, transitions of the output of summing circuit 505 are continuous or filtered or substantially continuous or filtered because discontinuities in the output of summing circuit 505 are generated because of the multibit resolution of the digital K value, instead of, for example, abrupt changes in which of amplifiers 504A and 504B are used to generate a signal for ADC 506.

Accordingly, the individual amplifiers gains combine to generate a weighted composite transfer function, and summing circuit 505 provides a continuous or filtered or substantially continuous or filtered logarithmic transfer function across the entire range of the value K.

Gain transition shaping circuit 510 may generate the value K using digital logic. For example, in some embodiments, gain transition shaping circuit 510 includes digital logic which generates the value K according to the signal flow graph of FIG. 4.

In some embodiments, gain transition shaping circuit 510 includes a comparator (not shown) or includes an ADC (not shown), such as a flash ADC. The comparator or ADC digitizes the analog input signal and generates a signal for the digital logic. In response to the signal, the digital logic changes the value K based on the digitized analog input signal. In some embodiments, gain transition shaping circuit 510 includes a comparator (not shown) which compares an output of ADC 506 to one or more threshold values. Accordingly, the changes in the value K are generated in response to the analog input signal transitioning across threshold boundaries. For example, gain transition shaping circuit 510 may determine that the gain should be changed based on one or more characteristics of the analog input signal, for example, including magnitude, average magnitude over a predetermined time, frequency, etc. In some embodiments, the digital logic has programmable thresholds. In some embodiments, the digital logic is hysteretic. In some embodiments, gain transition shaping circuit 510 includes a threshold detector which is used to compare the digitized analog input to a threshold to detect conditions for changing the gain of the logarithmic amplifier system 500.

In some embodiments, gain transition shaping circuit 510 includes a threshold detector which is used to compare the analog input to a threshold to detect conditions for changing the gain of the logarithmic amplifier system 500.

Analog-to-digital converter (ADC) 506 has an input coupled to the output of the summing circuit 505 and is configured to generate a digital representation of the logarithmically compressed analog signal received from summing circuit 505.

In some embodiments, gain adjust circuit 530 generates an output that provides a linearized digital signal by applying an anti-logarithmic transfer function to the digital logarithmic signal received on from ADC 506, where the anti-logarithmic transfer function is a result of input from gain calibration circuit 532. Accordingly, in some embodiments, signal compression is performed in the analog domain using the continuous or filtered or substantially continuous or filtered approach described above, and the signal decompression is performed in the digital domain.

In some embodiments, logarithmic amplifier system 500 includes an optional offset calibration capability provided, in part, by summing circuit 520 and offset register 522. In some embodiments, logarithmic amplifier system 500 includes an undesirable parasitic offset, which may be calibrated for. For example, a calibration routine may be performed to determine one or more offset values for offset register 522. In addition, during normal operation, summing circuit 520 adds an offset value to the digital representation of the logarithmically compressed analog signal generated by ADC 506.

In some embodiments, during the calibration routine, a 0 volts or minimum scale analog signal is input to the logarithmic amplifier system 500 as the analog input signal, and a first output of the ADC 506 is measured with the value K set to 1, and a second output of the ADC 506 is measured with the value K set to 0. In addition, the offset register 522 may be programmed with one or more offset values based on measurements taken during the calibration routine. For example, offset register 522 may be programmed with a linear series of offset values. In some embodiments, the linear series starts from a first offset value which compensates for the offset of amplifier 504A, as determined based on the second output and linearly steps to a second offset value which compensates for the offset of amplifier 504B, as determined based on the first output.

In normal operation, a particular offset value of the linear series is selected based on a current value of K.

In some embodiments, other offset calibration routines and offset calibration techniques are used. For example, in some embodiments, a single offset value is programmed into offset register 522, based, for example, on an average of a first offset value which compensates for the offset of amplifier 504A, as determined based on the second output and a second offset value which compensates for the offset of amplifier 504B, as determined based on the first output.

In some embodiments, efficient adaptive algorithms are used. For example, a gradient based algorithm may be used to determine offset values based on continuous or repeated monitoring.

In some embodiments, logarithmic amplifier system 500 includes an optional gain calibration capability provided, in part, by adjust circuit 530, optional gain calibration circuit 532, and optional gain register 534. In some embodiments, a gain of logarithmic amplifier system 500 may be adjusted to a particular target gain.

For example, a gain calibration routine may be performed to determine one or more gain calibration values for gain register 534. In addition, during normal operation, optional gain adjust circuit 530 multiplies or divides the digital representation of the logarithmically compressed analog signal from ADC 506 (and optionally adjusted by optional offset summing circuit 520) by a value determined by optional gain calibration circuit 532 based on the gain calibration values stored in gain register 534 and based on the value K. The multiplication or division by gain adjust circuit 530 results in an anti-logarithmic transfer function being applied to the signal from ADC 506.

In some embodiments, during the gain calibration routine, a static full scale analog signal is input to the logarithmic amplifier system 500 as the analog input signal, and a first output of the ADC 506 is measured with the value K set to 1, and a second output of the ADC 506 is measured with the value K set to 0. In addition, the gain register 534 may be programmed with one or more offset values based on measurements taken during the calibration routine. For example, gain register 534 may be programmed with a linear series of gain calibration values. In some embodiments, the linear series starts from a first gain calibration value which compensates for the gain offset of amplifier 504A, as determined based on the second output and linearly steps to a second gain calibration value which compensates for the gain mismatch of amplifier 504B, as determined based on the first output.

In normal operation, a particular gain calibration value of the linear series is selected based on a current value of K.

In some embodiments, other gain calibration routines and gain calibration techniques are used. For example, in some embodiments, a single gain calibration value is programmed into gain register 534, based, for example, on an average of a first gain calibration value which compensates for the gain calibration of amplifier 504A, as determined based on the second output and a second gain calibration value which compensates for the gain calibration of amplifier 504B, as determined based on the first output.

In embodiments using more than two amplifiers, similar principles may be used. For example, in some embodiments, the logarithmic amplifier system includes one or more additional amplifiers each having an input connected to the output of amplifier 504B, and each having a different gain equal to the desired gain of the path defined by the amplifier divided by gain B. Accordingly, the amplifiers of the logarithmic amplifier system form a series of amplifiers, each having greater gain than the previous. In addition, each pair of amplifiers which are adjacent in order of amplification has a pair of multipliers analogous to multipliers 503A and 503B in their relationship with amplifiers 504A and 504B, and in their relationship to one another as far as their K and 1-K multiplication factors.

Accordingly, in embodiments using more than two amplifiers, the first and last amplifiers in the series are respectively part of a first and last pair of adjacent amplifiers, and are not part of another pair of adjacent amplifiers. Therefore, the first and last amplifiers in the series each have one multiplier between their output and an input of the summing circuit. Furthermore, the amplifiers between the first and last amplifiers in the series are each part of two pairs of adjacent amplifiers. Accordingly, the amplifiers between the first and last amplifiers in the series each have a series cascade of two multipliers between their output and an input of the summing circuit, where a first of the two multipliers shares a K and 1-K relationship with the multiplier of the adjacent amplifier having a lesser gain, and where a second of the two multipliers shares a K and 1-K relationship with the multiplier of the adjacent amplifier having a greater gain.

In operation, in embodiments using more than two amplifiers, the analog signal is monitored to determine whether a higher gain or lower gain amplifier is to be used. In response to the analog input signal indicating a change is to be made in the gain of logarithmic amplifier system from a first gain to a second gain, a gain change trigger signal is generated to cause a smooth change in the K value for the multipliers of a pair of amplification-adjacent amplifiers having the first and second gains. The changing K value for the multipliers causes the gain of the logarithmic amplifier system to change from the first gain to the second gain according to the principles discussed herein with respect to changing the gain of the logarithmic amplifier system between that of amplifier 504A and that of amplifier 504B.

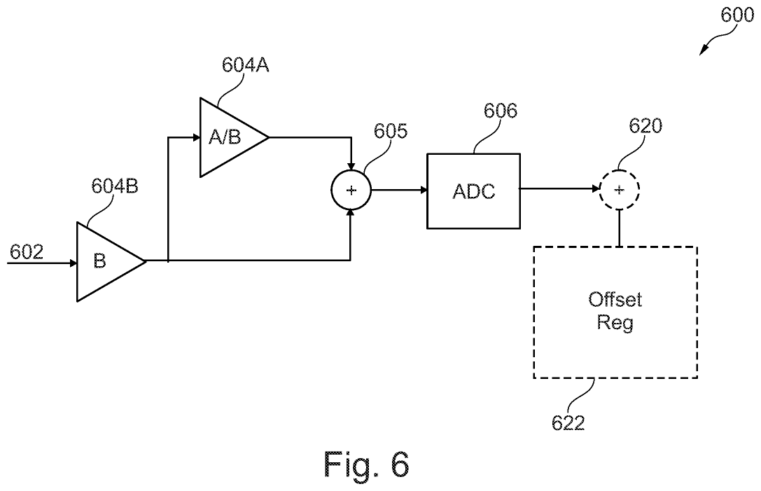

FIG. 6 illustrates various aspects for an embodiment using two amplifiers, but can be extended to any number of amplifiers. The two amplifiers/samplers present two different signal path gains. These gains can be switched smoothly by means of a control signal which fades-in and out both channels simultaneously. The control signal avoids fast jumps (discontinuities). As a result, the filter typically seen in related or similar circuits is avoided.

FIG. 6 is a logarithmic amplifier system 600 comprising a quantized analog logarithmic programmable gain amplifier (PGA) having individual amplifiers 604A and 604B each receiving an analog input signal at node 602 (which may be generated by a MEMS device, not shown in FIG. 6). Amplifier 604A has a gain of A/B and amplifier 604B has a gain of B. In some embodiments, A is greater than B. Logarithmic amplifier system 600 also includes summing circuit 605, and analog-to-digital converter (ADC) 606. In some embodiments, logarithmic amplifier system 600 includes optional offset summing circuit 620 and optional offset register 622.

Each individual amplifier 604A and 604B has a linear or substantially linear gain until it saturates for a given (increasing) maximum amplitude input signal. While two individual amplifiers are shown in FIG. 6, any number greater than or equal to two can be used.

In the illustrated embodiment, amplifier 604A has gain of A/B. In alternative embodiments, amplifier 604A has a different gain value. Amplifier 604A is configured to generate a signal for summing circuit 605 which is a multiplied version of analog input signal at node 602, where the gain of amplifier 604A times the gain of amplifier 604B determines the multiplication factor.

In the illustrated embodiment, amplifier 604B has a gain of B. In alternative embodiments, amplifier 604A has a different gain value. Amplifier 604B is configured to generate a signal for summing circuit 605 which is a multiplied version of the analog input signal at node 602, where the gain of amplifier 604B determines the multiplication factor.

Accordingly, summing circuit 605 receives a signal which is the analog input signal times the gain B from amplifier 604B and receives a signal which is the analog input signal times A from amplifier 604A. The summing circuit 605 generates a signal for ADC 606 which is a composite piece-wise linear logarithmic transfer function of the analog input signal.

An advantage of logarithmic amplifier system 600 is that when the amplifier 604A saturates, there is no capacitive kickback to the device generating the analog input signal through node 602. In contrast, circuits where multiple amplifiers receive the analog input signal, each amplifier presents a voltage dependent input capacitance. While the voltage dependent input capacitance may be bootstrapped for small signal amplitudes, it may be equal to the full input MOSFET gate to source capacitance at full scale (saturation) signal levels.

This “quantized” approach advantageously provides a signal processing system wherein, in embodiments having offset calibration, only one offset (the average of each of the individual amplifiers) is corrected, the anti-logarithmic digital signal processing can be simplified, a quasi-constant SNR can be maintained over the input signal range, and the SNR can be tailored while the total system area can be reduced. In some embodiments the ADC integrated circuit area can be reduced due to the use of smaller sampling capacitors.

Analog-to-digital converter (ADC) 606 has an input coupled to the output of the summing circuit 605 and is configured to generate a digital representation of the logarithmically compressed analog signal received from summing circuit 605.

In some embodiments, logarithmic amplifier system 600 includes an optional offset calibration capability provided, in part, by summing circuit 620 and offset register 622. In some embodiments, logarithmic amplifier system 600 includes an undesirable parasitic offset, which may be calibrated for. For example, a calibration routine may be performed to determine one or more offset values for offset register 622. In addition, during normal operation, summing circuit 620 adds an offset value to the digital representation of the logarithmically compressed analog signal generated by ADC 606.

In some embodiments, during the calibration routine, a 0 volts or minimum scale analog signal is input to the logarithmic amplifier system 600 as the analog input signal, and a first output of the ADC 606 is measured. In addition, the offset register 622 may be programmed with one or more offset values based on measurements taken during the calibration routine. For example, offset register 622 may be programmed with an offset value which compensates for the offset of amplifiers 604A and 604B, as determined based on the first output of the ADC 606.

In normal operation, a particular offset value of the linear series is selected based on a current value of K.

In some embodiments, other offset calibration routines and offset calibration techniques are used. For example, in some embodiments, during the calibration routine, a 0 v or minimum scale analog signal is input to the logarithmic amplifier system 600 as the analog input signal, and a first output of the ADC 606 is measured, and a second output of the ADC 606 is measured with a full scale analog signal input to the logarithmic amplifier system 600 as the analog input signal. In addition, the offset register 622 may be programmed with one or more offset values based on measurements taken during the calibration routine. For example, offset register 622 may be programmed with a linear series of offset values. In some embodiments, the linear series starts from a first offset value which compensates for the offset as determined based on the second output and linearly steps to a second offset value which compensates for the offset as determined based on the first output.

In some embodiments, efficient adaptive algorithms are used. For example, a gradient based algorithm may be used to determine offset values based on continuous or repeated monitoring.

In some embodiments, to reconstruct a digital representation of the analog input signal, a digital anti-logarithmic component (not shown) generates an output that provides a linearized digital signal by applying an anti-logarithmic transfer function to the digital logarithmic signal received on from ADC 606. Accordingly, in some embodiments, signal compression is performed in the analog domain using the continuous or filtered or substantially continuous or filtered approach described above, and the signal decompression is performed in the digital domain.

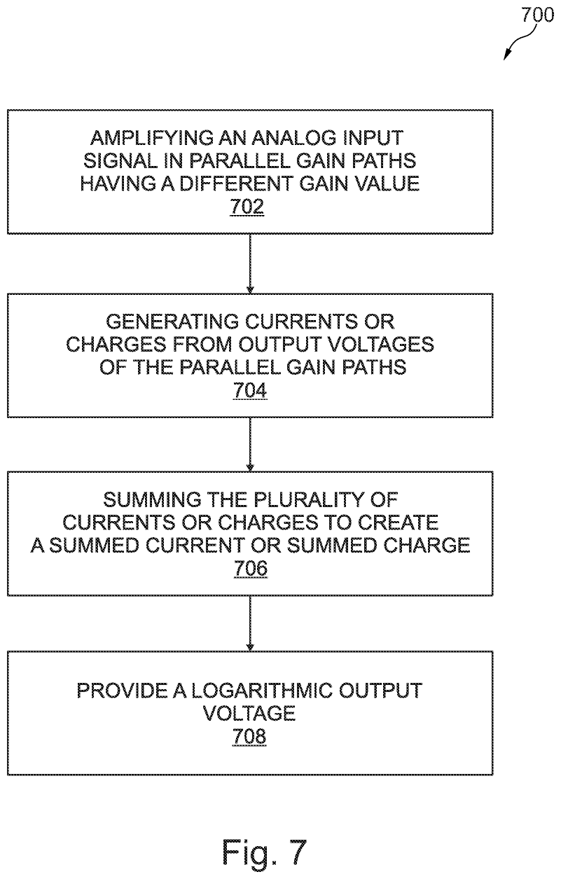

FIG. 7 is a flowchart of a method 700 according to some embodiments. Method 700 includes amplifying an analog input signal in a plurality of parallel gain paths, wherein each of the parallel gain paths comprises a different gain value at step 702; generating a plurality of currents or charges from a plurality of output voltages of the parallel gain paths at step 704; and providing an output voltage at step 708, where the output voltage approximates a logarithmic characteristic.

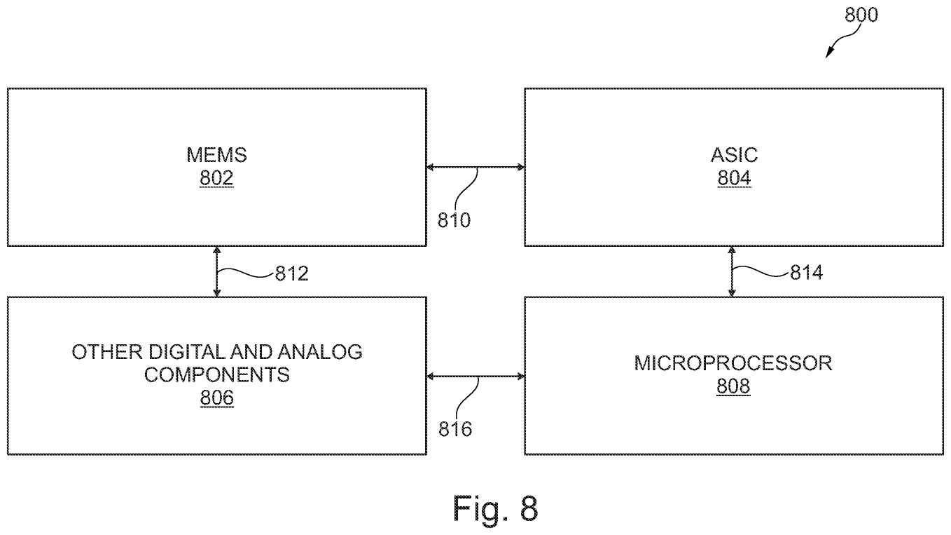

FIG. 8 is a block diagram for a digital microphone product 800 including a logarithmic amplifier system, for example, as described above. Digital microphone product 800 includes MEMS device 802 and ASIC 804. MEMS device 802 can comprise a capacitive MEMS device that generates an analog voltage in response to received sound waves. ASIC 804 can comprise the logarithmic amplifier system and an anti-logarithmic digital component, for example, as previously described. The MEMS device 802 and ASIC 804 are in communication via bidirectional bus 810. MEMS device 802 and ASIC 804 can be packaged together to form a single digital product, such as a digital microphone. In some embodiments, digital microphone product 800 can also include other digital and analog components 806, such as additional filters, amplifiers, and other similar components. The other digital and analog components 806 can communicate with MEMS device 802 through bidirectional bus 812. In some embodiments, digital microphone product 800 can also include a microprocessor 808, which can communicate with ASIC 804 and the other digital and analog components 806 through bidirectional bus 814 and bidirectional bus 816. For example, microprocessor 808 can generate clock signals and receive data from ASIC 804. In other embodiments, microprocessor 808 can provide the functionality of digital or software components that would otherwise be resident on ASIC 804.

Embodiments of the present invention are summarized here. Other embodiments can also be understood from the entirety of the specification and the claims filed herein.

One embodiment is a logarithmic amplifier system, including first and second amplifiers, the first amplifier having a first gain, and the second amplifier having a second gain; a first multiplier having an input connected to an output of the first amplifier, and being configured to output a first multiplied signal based on an output signal of the first amplifier and based on a received first multiplication factor equal to a value K; a second multiplier having an input connected to an output of the second amplifier, and being configured to output a second multiplied signal based on an output signal of the second amplifier and based on a received second multiplication factor equal to 1 minus the value K; a transition shaping circuit configured to generate the value K, where the transition shaping circuit is configured to change the value K from 0 to 1 with a filtered transfer function; and a summing circuit having inputs coupled to outputs of the first multiplier and the second multiplier. In some embodiments, the transition shaping circuit is configured to change the value K in response to a trigger signal generated based on one or more characteristics of an analog signal at an input of the first amplifier or generated based on one or more characteristics of a digitized version of the analog signal at the input of the first amplifier. In some embodiments, the transition shaping circuit is configured to change the value K in response to a filtered version of the trigger signal. In some embodiments, the transition shaping circuit is configured to change the value K using a digital processor configured to process the filtered version of the trigger signal. In some embodiments, the transition shaping circuit is configured to change the value K from a first of a minimum and a maximum to the other of the minimum or maximum strictly monotonically, and where the transition shaping circuit is configured to change the value K from the other of the minimum or maximum to the first of the minimum and the maximum by changing the value K from the other of the minimum or maximum to a midpoint value between the minimum and the maximum, and to subsequently change the value K from the midpoint value to the first of the minimum and the maximum. In some embodiments, the transition shaping circuit is configured to change the value K from one of a minimum and a maximum to a midpoint value between the minimum and the maximum, and to subsequently change the value K from the midpoint value to the one of the minimum and the maximum. In some embodiments, the first and second amplifiers have inputs connected to a same analog signal input. In some embodiments, the second amplifier has an input connected to an output connection of the first amplifier. In some embodiments, the logarithmic amplifier system further includes an analog-to-digital converter (ADC) configured to generate a digital representation of an analog output signal from the summing circuit. In some embodiments, the logarithmic amplifier system further includes an offset summing circuit; and an offset register, where the offset summing circuit is configured to generate an offset calibrated analog output signal based on the digital representation of the analog output signal and based on one or more offset values received from the offset register, and where the offset values are determined based on an offset calibration routine. In some embodiments, the logarithmic amplifier system further includes a gain adjust circuit; a gain calibration circuit; and a gain register, where the gain adjust circuit is configured to multiply or divide the offset calibrated analog output signal by a value to apply an anti-logarithmic transfer function to the offset calibrated analog output signal, where the value is determined by the gain calibration circuit based on one or more gain calibration values stored in the gain register and based on the value K, and where the gain calibration values are determined based on a gain calibration routine.

Another embodiment is a method of using a logarithmic amplifier system, the method including generating a first amplified signal based on an analog input and based on a first gain; generating a second amplified signal based on the analog input and based on a second gain; generating a first multiplied signal based on the first amplified signal and based on a first multiplication factor equal to a value K; generating a second multiplied signal based on the second amplified signal and based on a second multiplication factor equal to 1 minus the value K; changing the value K from 0 to 1 with a filtered transfer function; and generating an analog output signal by summing the first and second multiplied signals. In some embodiments, the method further includes changing the value K in response to a trigger signal generated based on one or more characteristics of the analog input or generated based on one or more characteristics of a digitized version of the analog input. In some embodiments, the method further includes changing the value K in response to a filtered version of the trigger signal.

Another embodiment is a digital microphone, including a MEMS device configured to generate an analog signal; and a logarithmic amplifier system, including first and second amplifiers, the first amplifier having a first gain, and the second amplifier having a second gain; a first multiplier having an input connected to an output of the first amplifier, and being configured to output a first multiplied signal based on an output signal of the first amplifier and based on a received first multiplication factor equal to a value K; a second multiplier having an input connected to an output of the second amplifier, and being configured to output a second multiplied signal based on an output signal of the second amplifier and based on a received second multiplication factor equal to 1 minus the value K; a transition shaping circuit configured to generate the value K, where the transition shaping circuit is configured to change the value K from 0 to 1 with a filtered transfer function; and a summing circuit having inputs coupled to outputs of the first multiplier and the second multiplier. In some embodiments, the transition shaping circuit is configured to change the value K in response to a trigger signal generated based on one or more characteristics of an analog signal at an input of the first amplifier or generated based on one or more characteristics of a digitized version of the analog signal at the input of the first amplifier. In some embodiments, the transition shaping circuit is configured to change the value K in response to a filtered version of the trigger signal. In some embodiments, the transition shaping circuit is configured to change the value K using a digital processor configured to process the filtered version of the trigger signal. In some embodiments, the transition shaping circuit is configured to change the value K from a first of a minimum and a maximum to the other of the minimum or maximum strictly monotonically, and where the transition shaping circuit is configured to change the value K from the other of the minimum or maximum to the first of the minimum and the maximum by changing the value K from the other of the minimum or maximum to a midpoint value between the minimum and the maximum, and to subsequently change the value K from the midpoint value to the first of the minimum and the maximum. In some embodiments, the transition shaping circuit is configured to change the value K from one of a minimum and a maximum to a midpoint value between the minimum and the maximum, and to subsequently change the value K from the midpoint value to the one of the minimum and the maximum.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A logarithmic amplifier system, comprising:
first and second amplifiers, the first amplifier having a first gain, and the second amplifier having a second gain;
a first multiplier having an input connected to an output of the first amplifier, and being configured to output a first multiplied signal based on an output signal of the first amplifier and based on a received first multiplication factor equal to a value K;
a second multiplier having an input connected to an output of the second amplifier, and being configured to output a second multiplied signal based on an output signal of the second amplifier and based on a received second multiplication factor equal to 1 minus the value K;
a transition shaping circuit configured to generate the value K, wherein the transition shaping circuit is configured to change the value K from 0 to 1 with a filtered transfer function; and
a summing circuit having inputs coupled to outputs of the first multiplier and the second multiplier.

2. The logarithmic amplifier system of claim 1, wherein the transition shaping circuit is configured to change the value K in response to a trigger signal generated based on one or more characteristics of an analog signal at an input of the first amplifier or generated based on one or more characteristics of a digitized version of the analog signal at the input of the first amplifier.

3. The logarithmic amplifier system of claim 2, wherein the transition shaping circuit is configured to change the value K in response to a filtered version of the trigger signal.

4. The logarithmic amplifier system of claim 3, wherein the transition shaping circuit is configured to change the value K using a digital processor configured to process the filtered version of the trigger signal.

5. The logarithmic amplifier system of claim 1, wherein the transition shaping circuit is configured to change the value K from a first of a minimum and a maximum to the other of the minimum or maximum strictly monotonically, and wherein the transition shaping circuit is configured to change the value K from the other of the minimum or maximum to the first of the minimum and the maximum by changing the value K from the other of the minimum or maximum to a midpoint value between the minimum and the maximum, and to subsequently change the value K from the midpoint value to the first of the minimum and the maximum.

6. The logarithmic amplifier system of claim 1, wherein the transition shaping circuit is configured to change the value K from one of a minimum and a maximum to a midpoint value between the minimum and the maximum, and to subsequently change the value K from the midpoint value to the one of the minimum and the maximum.

7. The logarithmic amplifier system of claim 1, wherein the first and second amplifiers have inputs connected to a same analog signal input.

8. The logarithmic amplifier system of claim 1, wherein the second amplifier has an input connected to an output connection of the first amplifier.

9. The logarithmic amplifier system of claim 1, further comprising an analog-to-digital converter (ADC) configured to generate a digital representation of an analog output signal from the summing circuit.

10. The logarithmic amplifier system of claim 9, further comprising:
an offset summing circuit; and
an offset register,
wherein the offset summing circuit is configured to generate an offset calibrated analog output signal based on the digital representation of the analog output signal and based on one or more offset values received from the offset register, and wherein the offset values are determined based on an offset calibration routine.

11. The logarithmic amplifier system of claim 10, further comprising:
a gain adjust circuit;
a gain calibration circuit; and
a gain register,
wherein the gain adjust circuit is configured to multiply or divide the offset calibrated analog output signal by a value to apply an anti-logarithmic transfer function to the offset calibrated analog output signal, wherein the value is determined by the gain calibration circuit based on one or more gain calibration values stored in the gain register and based on the value K, and wherein the gain calibration values are determined based on a gain calibration routine.

12. A method of using a logarithmic amplifier system, the method comprising:
generating a first amplified signal based on an analog input and based on a first gain;
generating a second amplified signal based on the analog input and based on a second gain;
generating a first multiplied signal based on the first amplified signal and based on a first multiplication factor equal to a value K;
generating a second multiplied signal based on the second amplified signal and based on a second multiplication factor equal to 1 minus the value K;
changing the value K from 0 to 1 with a filtered transfer function; and
generating an analog output signal by summing the first and second multiplied signals.

13. The method of claim 12, further comprising changing the value K in response to a trigger signal generated based on one or more characteristics of the analog input or generated based on one or more characteristics of a digitized version of the analog input.

14. The method of claim 13, further comprising changing the value K in response to a filtered version of the trigger signal.

15. A digital microphone, comprising:
a MEMS device configured to generate an analog signal; and
a logarithmic amplifier system, comprising:
first and second amplifiers, the first amplifier having a first gain, and the second amplifier having a second gain;
a first multiplier having an input connected to an output of the first amplifier, and being configured to output a first multiplied signal based on an output signal of the first amplifier and based on a received first multiplication factor equal to a value K;
a second multiplier having an input connected to an output of the second amplifier, and being configured to output a second multiplied signal based on an output signal of the second amplifier and based on a received second multiplication factor equal to 1 minus the value K;
a transition shaping circuit configured to generate the value K, wherein the transition shaping circuit is configured to change the value K from 0 to 1 with a filtered transfer function; and
a summing circuit having inputs coupled to outputs of the first multiplier and the second multiplier.

16. The digital microphone of claim 15, wherein the transition shaping circuit is configured to change the value K in response to a trigger signal generated based on one or more characteristics of an analog signal at an input of the first amplifier or generated based on one or more characteristics of a digitized version of the analog signal at the input of the first amplifier.

17. The digital microphone of claim 16, wherein the transition shaping circuit is configured to change the value K in response to a filtered version of the trigger signal.

18. The digital microphone of claim 17, wherein the transition shaping circuit is configured to change the value K using a digital processor configured to process the filtered version of the trigger signal.

19. The digital microphone of claim 15, wherein the transition shaping circuit is configured to change the value K from a first of a minimum and a maximum to the other of the minimum or maximum strictly monotonically, and wherein the transition shaping circuit is configured to change the value K from the other of the minimum or maximum to the first of the minimum and the maximum by changing the value K from the other of the minimum or maximum to a midpoint value between the minimum and the maximum, and to subsequently change the value K from the midpoint value to the first of the minimum and the maximum.

20. The digital microphone of claim 15, wherein the transition shaping circuit is configured to change the value K from one of a minimum and a maximum to a midpoint value between the minimum and the maximum, and to subsequently change the value K from the midpoint value to the one of the minimum and the maximum.
